(19) United States
(12) Patent Application Publication
(10) Pub. No.: US 2025/0234690 A1
(43) Pub. Date: Jul. 17, 2025

(54) ELECTRONIC DEVICE AND SEMICONDUCTOR CHIP THEREOF

(71) Applicant: Innolux Corporation, Miaoli County (TW)

(72) Inventors: Shu-Ming Kuo, Miaoli County (TW); Tsau-Hua Hsieh, Miaoli County (TW); Jian-Jung Shih, Miaoli County (TW)

(73) Assignee: Innolux Corporation, Miaoli County (TW)

(21) Appl. No.: 18/981,634

(22) Filed: Dec. 15, 2024

Related U.S. Application Data
(60) Provisional application No. 63/620,892, filed on Jan. 15, 2024.

(30) Foreign Application Priority Data
Sep. 19, 2024 (CN) 202411309131.8

(51) Int. Cl. H10H 20/856; H01L 25/13; H10H 20/831; H10H 20/841; H10H 20/851; H10H 20/852; H10H 29/24; H10H 29/85

(52) U.S. Cl. CPC H10H 20/856; H01L 25/13; H10H 20/831; H10H 20/841; H10H 20/851; H10H 20/852; H10H 29/24; H10H 29/8517

(57) ABSTRACT

An electronic device includes a substrate, a circuit layer, and a semiconductor chip. The circuit layer is disposed on the substrate. The semiconductor chip is disposed on the substrate and electrically connected to the circuit layer. The semiconductor chip includes a semiconductor die, a filling layer, a first electrode, a second electrode, and a reflective layer. The semiconductor die includes a first type semiconductor layer, an active layer, and a second type semiconductor layer stacked in sequence. The filling layer surrounds the semiconductor die and includes a light conversion material. The first electrode is disposed on a first side of the semiconductor die and electrically connected to the first type semiconductor layer. The second electrode is disposed on a second side of the semiconductor die and electrically connected to the second type semiconductor layer.

### CROSS-REFERENCE TO RELATED APPLICATION

This application claims the priority benefit of U.S. provisional application Ser. No. 63/620,892, filed on Jan. 15, 2024, and China application serial no. 202411309131.8, filed on Sep. 19, 2024. The entirety of each of the above-mentioned patent applications is hereby incorporated by reference herein and made a part of this specification.

### BACKGROUND

### Technical Field

The disclosure relates to an electronic device and a semiconductor chip thereof, particularly to an electronic device and a semiconductor chip thereof that may improve light conversion efficiency or improve color purity.

### Description of Related Art

The electronic device or the splicing electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The disclosure provides an electronic device and a semiconductor chip thereof, which may improve light conversion efficiency or improve color purity.

According to an embodiment of the disclosure, the semiconductor chip includes a semiconductor die, a filling layer, a first electrode, a second electrode, and a reflective layer. The semiconductor die includes a first type semiconductor layer, an active layer, and a second type semiconductor layer stacked in sequence. The filling layer surrounds the semiconductor die and includes a light conversion material. The first electrode is disposed on a first side of the semiconductor die and electrically connected to the first type semiconductor layer. The second electrode is disposed on a second side of the semiconductor die and electrically connected to the second type semiconductor layer.

According to an embodiment of the disclosure, the electronic device includes a substrate, a circuit layer, and a semiconductor chip. The circuit layer is disposed on the substrate. The semiconductor chip is disposed on the substrate and electrically connected to the circuit layer. The semiconductor chip includes a semiconductor die, a filling layer, a first electrode, a second electrode, and a reflective layer. The semiconductor die includes a first type semiconductor layer, an active layer, and a second type semiconductor layer stacked in sequence. The filling layer surrounds the semiconductor die and includes a light conversion material. The first electrode is disposed on a first side of the semiconductor die and electrically connected to the first type semiconductor layer. The second electrode is disposed on a second side of the semiconductor die and electrically connected to the second type semiconductor layer.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of a semiconductor chip in the first embodiment of the disclosure.

FIG. 2 is a cross-sectional schematic view of a semiconductor chip in the second embodiment of the disclosure.

FIG. 3 is a cross-sectional schematic view of a semiconductor chip in the third embodiment of the disclosure.

FIG. 4 is a cross-sectional schematic view of an electronic device in an embodiment of the disclosure.

FIG. 5 is a cross-sectional schematic view of an electronic device in another embodiment of the disclosure.

FIG. 6 is an application of an electronic device in another embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a single constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect electrical connection means.

In some embodiments of the disclosure, an optical microscope (OM), a scanning electron microscope (SEM), a thin film thickness profilometer (α-step), an ellipsometer, or other suitable manners may be used to measure an area, a width, a thickness, or a height of each element or a distance or a spacing between elements. In detail, according to some embodiments, the scanning electron microscope may be used to obtain a cross-sectional structural image including the element to be measured and measure the area, the width, the thickness, or the height of each element or the distance or the spacing between the elements.

In the disclosure, the electronic device may include a display device, light emitting device, backlight device, virtual reality device, augmented reality (AR) device, antenna device, sensing device, tiled device, or any combination thereof, but not limited thereto. The display device may be a non-self-luminous display or a self-luminous display according to requirements, and may be a color display or a monochrome display according to requirements. The antenna device may be a liquid crystal type antenna device or a non-liquid crystal type antenna device. The sensing device may be a device for sensing capacitance, light, thermal energy, or ultrasound. The tiled device may be a display tiled device or an antenna tiled device, but not limited thereto. The electronic units in the electronic device may include passive components and active components, such as capacitors, resistors, inductors, diodes, transistors, etc. The diode may include a light emitting diode (LED) or a photodiode. The light emitting diode may include, for example, an organic light emitting diode (OLED), a mini LED, a micro LED, or a quantum dot LED, but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have peripheral systems such as driving systems, control systems, light source systems, etc. to support display devices, antenna devices, wearable devices (including augmented reality or virtual reality devices, for example), vehicle-mounted devices (including car windshields, for example), or tiled devices. It should be noted that the electronic device may be any permutation and combination of the above, but not limited thereto. The following will use the electronic device and the semiconductor chip therefore to explain the content of the disclosure, but the disclosure is not limited thereto.

It should be noted that in the following embodiments, without departing from the spirit of the disclosure, features in several different embodiments may be replaced, reorganized, and mixed to complete other embodiments. As long as the features of the embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

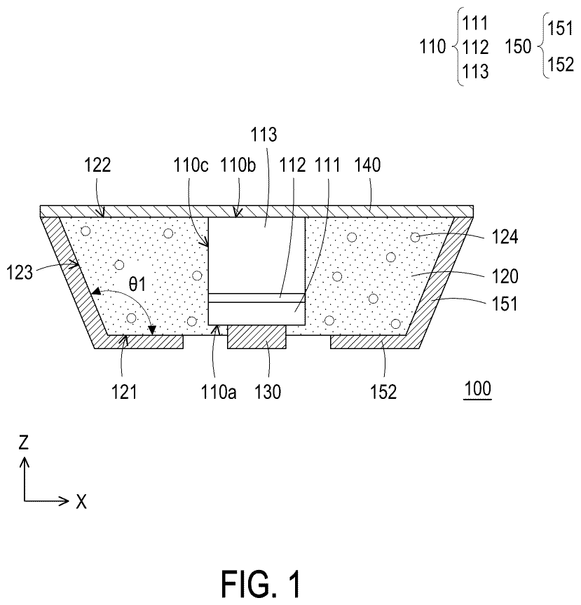

FIG. 1 is a cross-sectional schematic view of a semiconductor chip in the first embodiment of the disclosure. Referring to FIG. 1, a semiconductor chip 100 of the embodiment includes a semiconductor die 110, a filling layer 120, a first electrode 130, a second electrode 140, and a reflective layer 150.

Specifically, the semiconductor die 110 has a first side 110a, a second side 110b, and a side surface 110c. The first side 110a is opposite to the second side 110b, and the first side 110a faces the first electrode 130. The second side 110b is closer to the second electrode 140 than the first side 110a. The side surface 110c connects the first side 110a and the second side 110b. In the embodiment, the semiconductor die 110 may be a vertical type chip. In a direction Z (for example, a normal direction of the semiconductor chip 100), the semiconductor die 110 includes a first type semiconductor layer 111, an active layer 112, and a second type semiconductor layer 113 stacked in sequence. The first type semiconductor layer 111 is closer to the first electrode 130 than the second type semiconductor layer 113, and the active layer 112 is disposed between the first type semiconductor layer 111 and the second type semiconductor layer 113.

In the embodiment, the semiconductor die 110 may be a light emitting component (for example, an organic light emitting diode, a mini light emitting diode, a micro light emitting diode, or a quantum dot light emitting diode, but not limited thereto), and the active layer 112 may be a light emitting layer, a photosensitive layer, or an intrinsic layer, but not limited thereto. In the embodiment, the first type semiconductor layer 111 may be a P-type semiconductor layer, and the second type semiconductor layer 113 may be an N-type semiconductor layer, but not limited thereto. In some embodiments, the first type semiconductor layer may also be an N-type semiconductor layer, and the second type semiconductor layer may also be a P-type semiconductor layer.

The filling layer 120 surrounds the semiconductor die 110. The filling layer 120 may contact the side surface 110c of the semiconductor die 110. The filling layer 120 has a first surface 121, a second surface 122, and a side surface 123. The first surface 121 and the second surface 122 are opposite to each other, and the first surface 121 faces the first electrode 130. The second surface 122 is closer to the second electrode 140 than the first surface 121. The side surface 123 is disposed between the first surface 121 and the second surface 122, and the side surface 123 connects the first surface 121 and the second surface 122. In the embodiment, an angle θ1 between the side surface 123 and the first surface 121 has a taper angle, and the angle θ1 may be between 90 degrees and 170 degrees, between 90 degrees and 150 degrees, between 100 degrees and 170 degrees, or between 110 degrees and 150 degrees, so that the filling layer 120 may have a bowl-like structure, and the filling layer 120 may be combined with the reflective layer 150 to concentrate the light emission of the semiconductor die 110, reduce the light emission angle of the semiconductor die 110, or improve the light emission efficiency of the semiconductor die 110, but not limited thereto. In the embodiment, the materials of the filling layer 120 may include acrylic, epoxy, siloxane, silica, other transparent filling materials, or a combination thereof, but not limited thereto.

In the embodiment, the filling layer 120 may include a light conversion material 124, which may be used to convert short-wavelength light (for example: blue light) emitted by the semiconductor die 110 into long-wavelength light (for example: red light or green light). In the embodiment, the light conversion material 124 may include quantum dots, phosphors, fluorescent materials, other suitable light conversion materials, or a combination thereof, but not limited thereto.

The first electrode 130 is disposed on the first side 110a of the semiconductor die 110. The first electrode 130 may contact and be electrically connected to the first type semiconductor layer 111 of the semiconductor die 110. In some embodiments, there is an ohmic contact layer (not shown) between the first electrode 130 and the first type semiconductor layer 111, and the ohmic contact layer may include transparent conductive oxide. In the embodiment, the material of the first electrode 130 may include conductive materials with high reflective characteristics (for example, nickel, aluminum, silver, platinum, or a combination thereof, but not limited thereto), so that the first electrode 130 may be used to reflect the light emitted from the semiconductor die 110, improve the light emission efficiency of the semiconductor die 110, or allow the light emitted from the semiconductor die 110 to fully react with the light conversion material 124 to improve the light conversion efficiency.

The second electrode 140 is disposed on the second side 110b of the semiconductor die 110 and the second surface 122 of the filling layer 120. The second electrode 140 may connect to the reflective layer 150. The second electrode 140 may contact and be electrically connected to the second type semiconductor layer 113 of the semiconductor die 110. In the embodiment, the second electrode 140 may include conductive materials, which may include transparent conductive oxides (TCO), graphene, or metal. The transparent conductive oxides may include indium tin oxide (ITO), indium zinc oxide (IZO), or indium gallium oxide (IGO), or a combination thereof, but not limited thereto. The metal may include thin metal or metal grid, for example, a thin metal layer may be formed (such as a magnesium layer or a silver layer), or a metal grid layer with light-transmitting openings may be formed through screen printing or other patterning processes. In some embodiment, the second electrode 140 may include transparent conductive material.

The reflective layer 150 is disposed on the filling layer 120, and the reflective layer 150 is separated from the first electrode 130. The reflective layer 150 includes a first part 151 and a second part 152. The first part 151 is disposed on the side surface 123 of the filling layer 120, and the second part 152 is disposed on the first surface 121 of the filling layer 120. One side of the first part 151 may connect to the second electrode 140, and the other side of the first part 151 may connect to the second part 152; thereby, allowing the second part 152 be electrically connect to the second type semiconductor layer 113 of the semiconductor die 110 through the first part 151 and the second electrode 140. In the embodiment, the material of the reflective layer 150 may include conductive materials with high reflective characteristics, so that the reflective layer 150 may be used to concentrate the light emitted from the semiconductor die 110, reduce the light emission angle of the semiconductor die 110, improve the light emission efficiency of the semiconductor die 110, or allow the light emitted from the semiconductor die 110 to fully react with the light conversion material 124 to improve the light conversion efficiency. In the embodiment, the material of the reflective layer 150 may be the same as the material of the first electrode 130, but not limited thereto. The material of the reflective layer 150 may include silver, aluminum, tin, indium, copper, gold, or a combination thereof, but not limited thereto.

In the embodiment, the first type semiconductor layer 111 and the second type semiconductor layer 113 of the vertical semiconductor die 110 may be electrically connected to the first electrode 130 and the second part 152 of the reflective layer 150 respectively, and the first electrode 130 and the second part 152 may be disposed on the same side of the semiconductor chip 100 (or disposed on the same horizontal plane), so the semiconductor chip 100 may be a vertical embedded flip-chip (VEFC), and the semiconductor chip 100 may be easily detected and mass transferred. In some embodiments, a projection area of the first electrode 130 and the second part 152 on an X-Y plane is greater than a projection area of the semiconductor die 110 on the same X-Y plane, which facilitates the subsequent bonding process of the semiconductor chip 100.

Other embodiments will be listed below as illustrations. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

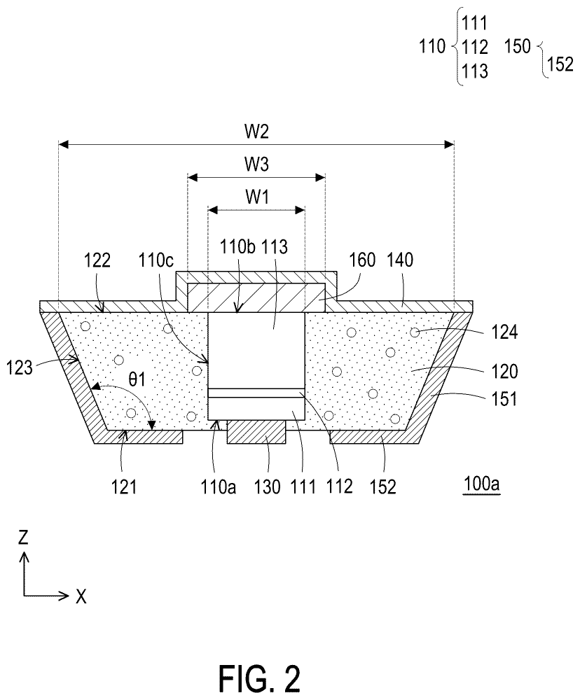

FIG. 2 is a cross-sectional schematic view of a semiconductor chip in the second embodiment of the disclosure. Please refer to FIG. 2 and FIG. 1 at the same time. A semiconductor chip 100a of the embodiment is similar to the semiconductor chip 100 in FIG. 1. The only difference between the two is that the semiconductor chip 100a of the embodiment further includes a light-shielding electrode 160.

Specifically, please refer to FIG. 2, the light-shielding electrode 160 is disposed on the second side 110b of the semiconductor die 110, and the light-shielding electrode 160 is disposed between the second type semiconductor layer 113 and the second electrode 140. In the direction Z (for example, the normal direction of the semiconductor chip 100a), the light-shielding electrode 160 may overlap with at least a part of the semiconductor die 110 and the second surface 122 of the filling layer 120. The light-shielding electrode 160 may contact and be electrically connected to the second type semiconductor layer 113 and the second electrode 140. In some embodiments, there is an ohmic contact layer (not shown) between the light-shielding electrode 160 and the second type semiconductor layer 113.

In the embodiment, the material of the light-shielding electrode 160 may include metal, such as gold, but not limited thereto. In the embodiment, relative to a visible light spectrum, a transmittance of the light-shielding electrode 160 may be less than a transmittance of the second electrode 140; thus, the probability of short-wavelength light (for example: blue light) emitted by the semiconductor die 110 being directly emitted to the outside of the semiconductor chip 100a without undergoing light conversion steps may be reduced, thereby improving light conversion efficiency of the semiconductor chip 100a or improving color purity of the semiconductor chip 100a.

In the embodiment, the semiconductor die 110 has a width W1, the second surface 122 of the filling layer 120 has a width W2, and the light-shielding electrode 160 has a width W3. The width W1 may be a maximum width measured along a direction X of the semiconductor die 110, the width W2 may be a maximum width measured along the direction X of the second surface 122 of the filling layer 120, and the width W3 may be a maximum width measured along the direction X of the light-shielding electrode 160. Direction X and direction Z are different directions, and direction X may be substantially perpendicular to direction Z, but not limited thereto. In the embodiment, the width W3 of the light-shielding electrode 160 may be greater than or equal to 30% of the width W1 of the semiconductor die 110, and the width W3 of the light-shielding electrode 160 may be less than or equal to 50% of the width W2 of the second surface 122 of the filling layer 120 (that is, 30%×W1≤W3≤50%×W2), to reduce the probability of short-wavelength light (for example: blue light) emitted by the semiconductor die 110 being directly emitted to the outside of the semiconductor chip 100a, but not limited thereto. In some embodiments, the width W1 ranges from 1 to 10 μm, and the width W2 ranges from 10 to 50 μm.

In the embodiment, in a top view (not shown) of the semiconductor chip 100a, the semiconductor die 110 has an area A1, the second surface 122 of the filling layer 120 has an area A2, and the light-shielding electrode 160 has an area A3. In the embodiment, the area A3 of the light-shielding electrode 160 may be greater than or equal to 10% of the area A1 of the semiconductor die 110, and the area A3 of the light-shielding electrode 160 may be less than or equal to 50% of the area A2 of the second surface 122 of the filling layer 120 (that is, 10%×A1≤A3≤50%×A2), to reduce the probability of short-wavelength light (for example: blue light) emitted by the semiconductor die 110 being directly emitted to the outside of the semiconductor chip 100a, but not limited thereto.

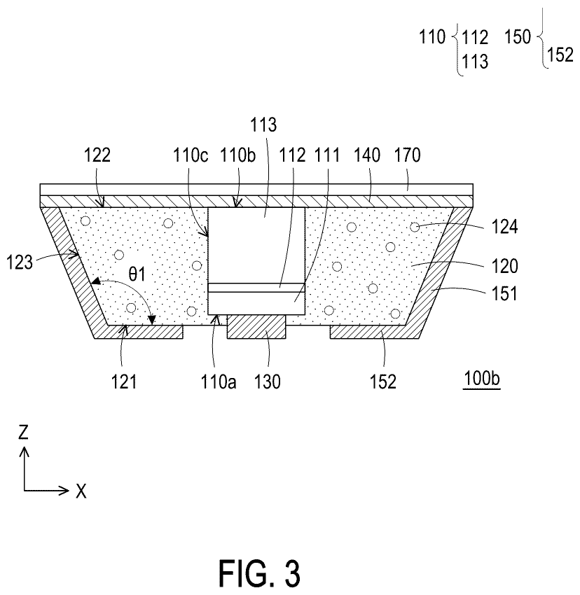

FIG. 3 is a cross-sectional schematic view of a semiconductor chip in the third embodiment of the disclosure. Please refer to FIG. 3 and FIG. 1 at the same time. A semiconductor chip 100b of the embodiment is similar to the semiconductor chip 100 in FIG. 1. The only difference between the two is that the semiconductor chip 100b of the embodiment further includes a distributed Bragg reflector (DBR) 170.

Specifically, referring to FIG. 3, the distributed Bragg reflector 170 is disposed on the second electrode 140, and the second electrode 140 is disposed between the distributed Bragg reflector 170 and the semiconductor die 110. In the embodiment, the distributed Bragg reflector 170 may be used to reflect short-wavelength light (for example: blue light) and allow long-wavelength light (for example: red light or green light) to pass through, to reduce the probability of short-wavelength light emitted by the semiconductor die 110 being directly emitted to the outside of the semiconductor chip 100b without undergoing light conversion steps, thereby improving light conversion efficiency of the semiconductor chip 100b or improving color purity of the semiconductor chip 100b.

For example, when the semiconductor die 110 emits blue light, a portion of the blue light directed towards the filling layer 120 containing red light conversion material may be first converted into red light by the light conversion steps, and then the converted red light may pass through the distributed Bragg reflector 170 and emits to the outside of the semiconductor chip 100b; another portion of the blue light directed towards the distributed Bragg reflector 170 cannot directly pass through the distributed Bragg reflector 170 and can be reflected by the distributed Bragg reflector 170, until the reflected blue light is converted into red light by the light conversion steps, then the converted red light may pass through the distributed Bragg reflector 170 and emits to the outside of the semiconductor chip 100b. By this design, the light emitted by the semiconductor chip 100b may be substantially red light, and the probability of the light emitted by the semiconductor chip 100b being doped with blue light may be reduced.

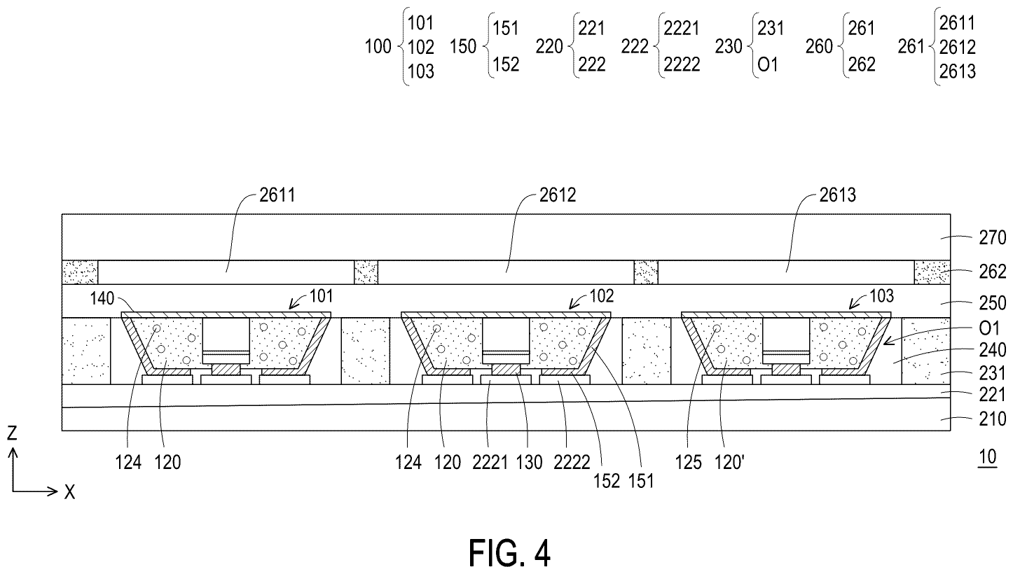

FIG. 4 is a cross-sectional schematic view of an electronic device in an embodiment of the disclosure. Referring to FIG. 4, an electronic device 10 of the embodiment includes a substrate 210, a circuit layer 220, a unit definition layer 230, a semiconductor chip 100, an underfill layer 240, an adhesive layer 250, a color filter layer 260, and a substrate 270.

Specifically, the substrate 210 may include a rigid substrate, a flexible substrate, or a combination thereof. For example, the materials of the substrate 210 may include glass, quartz, sapphire, ceramic, polycarbonate (PC), polyimide (PI), polyethylene terephthalate (PET), other suitable substrate materials, or a combination thereof, but not limited thereto.

The circuit layer 220 is disposed on the substrate 210. The circuit layer 220 may be an active driving circuit or a passive driving circuit to drive the semiconductor chip 100. The circuit layer 220 may include an insulating layer 221, a conductive layer 222, and metal wiring (not shown), etc. The conductive layer 222 is disposed on the insulating layer 221, and the conductive layer 222 may include pads 2221 and pads 2222 that are separated from each other. The metal wiring is disposed in the insulating layer 221. In the embodiment, the materials of the conductive layer 222 may include gold, tin, copper, other suitable conductive materials, or a combination thereof, but not limited thereto. The insulating layer 221 may be a single-layer structure or a multi-layer structure, and the materials of the insulating layer 221 may include organic materials, inorganic materials, or a combination thereof, but not limited thereto.

The unit definition layer 230 is disposed on the circuit layer 220. The unit definition layer 230 may include a partition 231 and an opening O1 for accommodating the semiconductor chip 100. The opening O1 may expose part of the insulating layer 221 in the circuit layer 220 and the pads 2221 and pads 2222 of the conductive layer 222. In the embodiment, the materials of the unit definition layer 230 may include organic photoresist, and the color of the unit definition layer 230 may be transparent, black, gray, or white, but not limited thereto.

The semiconductor chip 100 of the embodiment may be the semiconductor chip shown in FIG. 1, so it will not be repeated here. The semiconductor chip 100 is disposed on the substrate 210 and in the opening O1 of the unit definition layer 230. The semiconductor chip 100 may be bonded and electrically connected to the circuit layer 220 through the conductive layer 222. Specifically, the first electrode 130 of the semiconductor chip 100 may contact and be electrically connected to the pad 2221 of the conductive layer 222, and the second part 152 of the reflective layer 150 may contact and be electrically connected to the pad 2222 of the conductive layer 222. In the embodiment, the semiconductor chip 100 may include a first semiconductor chip 101, a second semiconductor chip 102, and a third semiconductor chip 103, to respectively emit light of different colors. For example, the first semiconductor chip 101 may emit red light, the second semiconductor chip 102 may emit green light, and the third semiconductor chip 103 may emit blue light, but not limited thereto. Among them, the filling layer 120 of the first semiconductor chip 101 and the second semiconductor chip 102 may include a light conversion material 124, while the filling layer 120′ of the third semiconductor chip 103 may include a scattering particle 125 (for example, titanium dioxide, but not limited thereto) and does not include a light conversion material.

The underfill layer 240 is disposed in the opening O1, and the underfill layer 240 may surround the semiconductor chip 100 to fix the semiconductor chip 100 in the opening O1. In the embodiment, the materials of the underfill layer 240 may include acrylic, epoxy, siloxane, silicon dioxide, other suitable adhesive materials, or a combination thereof, but not limited thereto.

The adhesive layer 250 is disposed on the unit definition layer 230. In the embodiment, the materials of the adhesive layer 250 may include optically clear adhesive (OCA), optical clear resin (OCR), other suitable transparent materials, or a combination thereof, but not limited thereto.

The color filter layer 260 is disposed on the semiconductor chip 100 and the adhesive layer 250. The color filter layer 260 includes a color filter unit 261 and a black matrix layer 262. In the direction Z (for example, the normal direction of the substrate 210 or the normal direction of the electronic device 10), the color filter unit 261 of the color filter layer 260 may overlap with and correspond to the semiconductor chip 100, and the black matrix layer 262 may overlap with and correspond to the partition 231 of the unit definition layer 230. In the embodiment, the color filter unit 261 may include a first color filter unit 2611, a second color filter unit 2612, and a third color filter unit 2613, to respectively allow light of different wavelengths to pass through; thus, the color filter unit 261 may be further used to improve the color purity of the semiconductor chip 100 or improve the ambient contrast ratio. For example, the first color filter unit 2611 may allow red light to pass through, the second color filter unit 2612 may allow green light to pass through, and the third color filter unit 2613 may allow blue light to pass through, but not limited thereto.

The substrate 270 is disposed on the color filter layer 260, and the substrate 270 is disposed relative to the substrate 210. The substrate 270 may include a rigid substrate, a flexible substrate, or a combination thereof. For example, the materials of the substrate 270 may include glass, quartz, sapphire, ceramic, polycarbonate, polyimide, polyethylene terephthalate, other suitable substrate materials, or a combination thereof, but not limited thereto.

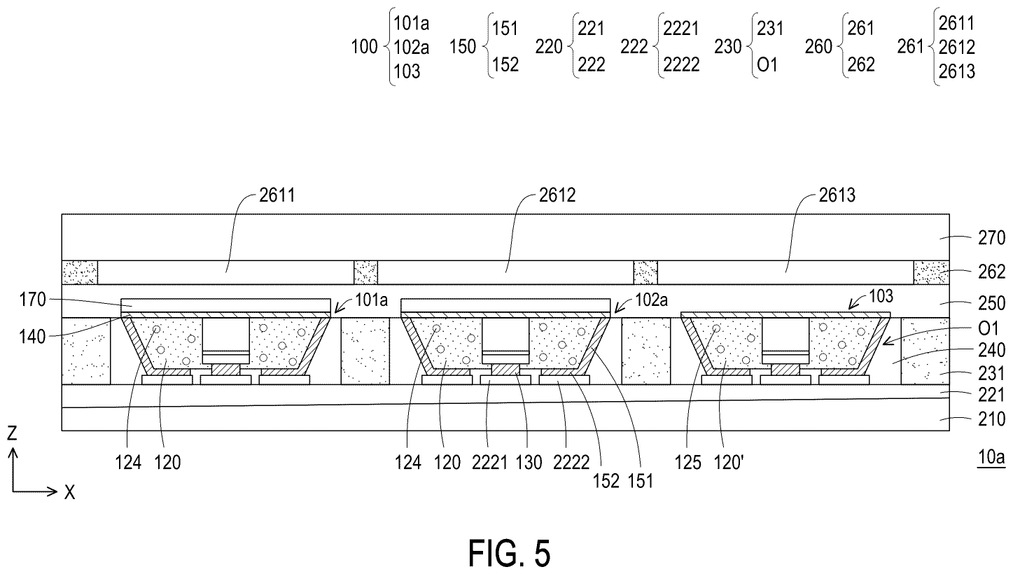

FIG. 5 is a cross-sectional schematic view of an electronic device in another embodiment of the disclosure. Please refer to FIG. 5 and FIG. 4 at the same time. An electronic device 10a of the embodiment is similar to the electronic device 10 in FIG. 4. The only difference between the two is that in the electronic device 10a of the embodiment, the first semiconductor chip 101a and the second semiconductor chip 102a in the semiconductor chip 100 further include a distributed Bragg reflector 170, and the third semiconductor chip 103 in the semiconductor chip 100 does not require be configured with a distributed Bragg reflector 170.

Specifically, referring to FIG. 5, the distributed Bragg reflector 170 is disposed on the opening O1 of the unit definition layer 230, and the distributed Bragg reflector 170 is disposed on the second electrode 140 of the first semiconductor chip 101a and the second semiconductor chip 102a. In the direction Z (for example, the normal direction of the substrate 210 or the normal direction of the electronic device 10), the distributed Bragg reflector 170 may overlap with and correspond to the first semiconductor chip 101a and the second semiconductor chip 102a in the semiconductor chip 100. In the embodiment, the distributed Bragg reflector 170 may be used to reflect short-wavelength light (for example: blue light) and allow long-wavelength light (for example: red light or green light) to pass through, so as to reduce the probability of short-wavelength light emitted by the first semiconductor chip 101a and the second semiconductor chip 102a being directly emitted without undergoing light conversion steps, thereby improving the color purity of the semiconductor chip.

Although FIG. 5 schematically shows the distributed Bragg reflector 170 as a single layer, the disclosure does not limit the number of layers of the distributed Bragg reflector 170. In some embodiments, multiple layers of distributed Bragg reflectors may be stacked according to design or usage requirements to selectively allow light of different colors to pass through.

The color filter layer 260 is disposed on the distributed Bragg reflector 170, and the distributed Bragg reflector 170 is disposed between the color filter layer 260 and the semiconductor chip 100.

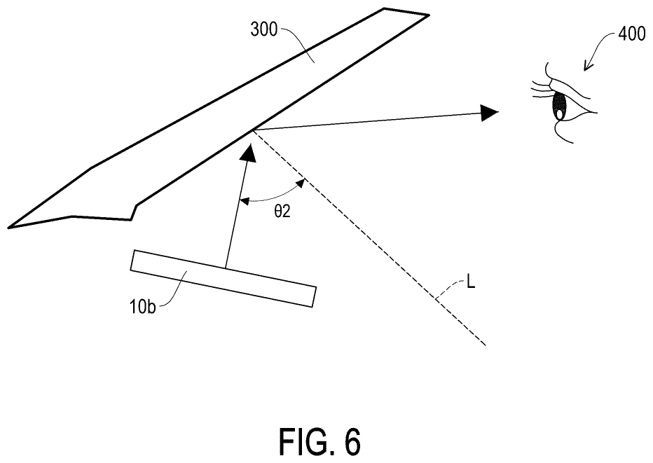

FIG. 6 is an application of an electronic device in another embodiment of the disclosure. Referring to FIG. 6, the electronic device 10b of the disclosure may be a head-up display (HUD) or panoramic head-up display (PHUD) for vehicles, but not limited thereto.

The electronic device 10b of the disclosure may include the semiconductor chip 100 as shown in FIG. 1, the semiconductor chip 100a as shown in FIG. 2, the semiconductor chip 100b as shown in FIG. 3, the electronic device 10 as shown in FIG. 4, or the electronic device 10a as shown in FIG. 5, to provide highly concentrated light or high-brightness light, thereby reducing the influence of external ambient light.

In the embodiment, relative to a normal L of a windshield 300, an image of the electronic device 10b may, for example, be projected onto the windshield 300 at an incident angle θ2 of 30 degrees to 70 degrees, so that a driver 400 may see the image of the electronic device 10b on the windshield 300.

In summary, in the electronic device and semiconductor chip thereof of the embodiment of the disclosure, since the filling layer includes the light conversion material and the reflective layer is disposed on the filling layer, the light emitted by the semiconductor die may fully react with the light conversion material, thereby improving the light conversion efficiency. Furthermore, by disposing the light-shielding electrode between the second type semiconductor layer and the second electrode, disposing the distributed Bragg reflector on the second electrode, or disposing the color filter layer on the semiconductor chip, the color purity of the semiconductor chip may be improved.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A semiconductor chip, comprising:
a semiconductor die, comprising a first type semiconductor layer, an active layer, and a second type semiconductor layer stacked in sequence;
a filling layer, surrounding the semiconductor die and comprising a light conversion material;
a first electrode, disposed on a first side of the semiconductor die and electrically connected to the first type semiconductor layer;
a second electrode, disposed on a second side of the semiconductor die and electrically connected to the second type semiconductor layer; and
a reflective layer, disposed on the filling layer.

2. The semiconductor chip according to claim 1, wherein the second electrode connects the reflective layer.

3. The semiconductor chip according to claim 1, wherein the filling layer comprises a first surface, a second surface opposite to the first surface, and a side surface disposed between the first surface and the second surface, and the reflective layer comprises a first part disposed on the side surface.

4. The semiconductor chip according to claim 3, wherein the reflective layer further comprises a second part disposed on the first surface, the second electrode connects the first part, and the first part connects the second part.

5. The semiconductor chip according to claim 3, wherein the reflective layer and the first electrode comprise the same materials.

6. The semiconductor chip according to claim 3, wherein the side surface has an angle relative to the first surface, and the angle is between 90 degrees and 150 degrees.

7. The semiconductor chip according to claim 6, wherein the angle is between 110 degrees and 150 degrees.

8. The semiconductor chip according to claim 3, further comprising:
a light-shielding electrode, disposed between the second type semiconductor layer and the second electrode, and electrically connected to the second type semiconductor layer and the second electrode.

9. The semiconductor chip according to claim 8, wherein relative to a visible light spectrum, a transmittance of the light-shielding electrode is less than a transmittance of the second electrode.

10. The semiconductor chip according to claim 8, wherein the light-shielding electrode overlaps with at least a part of the second surface.

11. The semiconductor chip according to claim 8, wherein a width of the light-shielding electrode is greater than or equal to 30% of a width of the semiconductor die, and the width of the light-shielding electrode is less than or equal to 50% of a width of the second surface of the filling layer.

12. The semiconductor chip according to claim 8, wherein an area of the light-shielding electrode is greater than or equal to 10% of an area of the semiconductor die, and the area of the light-shielding electrode is less than or equal to 50% of an area of the second surface of the filling layer.

13. The semiconductor chip according to claim 1, further comprising:
a distributed Bragg reflector, disposed on the second electrode.

14. The semiconductor chip according to claim 1, wherein the filling layer contacts a side surface of the semiconductor die.

15. An electronic device, comprising:
a substrate;
a circuit layer, disposed on the substrate; and
a semiconductor chip, disposed on the substrate and electrically connected to the circuit layer, wherein the semiconductor chip comprises:
a semiconductor die, comprising a first type semiconductor layer, an active layer, and a second type semiconductor layer stacked in sequence;
a filling layer, surrounding the semiconductor die and comprising a light conversion material;
a first electrode, disposed on a first side of the semiconductor die and electrically connected to the first type semiconductor layer;
a second electrode, disposed on a second side of the semiconductor die and electrically connected to the second type semiconductor layer; and
a reflective layer, disposed on the filling layer.

16. The electronic device according to claim 15, further comprising:
a unit definition layer, disposed on the circuit layer and comprising an opening for accommodating the semiconductor chip.

17. The electronic device according to claim 16, further comprising:
an underfill layer, disposed in the opening and surrounding the semiconductor chip.

18. The electronic device according to claim 16, wherein the semiconductor chip further comprises:
a distributed Bragg reflector, disposed on the opening of the unit definition layer and overlapping with the semiconductor chip.

19. The electronic device according to claim 18, further comprising:
a color filter layer, disposed on the distributed Bragg reflector and overlapping with the semiconductor chip.

20. The electronic device according to claim 15, wherein the semiconductor chip is a vertical embedded flip-chip.
